(19) United States
(12) Patent Application Publication
(10) Pub. No.: US 2026/0129794 A1
(43) Pub. Date: May 7, 2026

(54) LIQUID-COOLED POWER SUPPLY CHASSIS AND LIQUID-COOLED POWER SUPPLY CABINET USING THE SAME

(71) Applicant: LITE-ON TECHNOLOGY CORPORATION, Taipei (TW)

(72) Inventors: Shu-Wei CHU, Taipei (TW); Chen-Chih Lee, Taipei (TW); Wei-Hao Liang, Taipei (TW)

(21) Appl. No.: 19/171,397

(22) Filed: Apr. 7, 2025

Related U.S. Application Data
(60) Provisional application No. 63/716,784, filed on Nov. 6, 2024.

(30) Foreign Application Priority Data
Feb. 18, 2025 (TW) 114105906

(51) Int. Cl. H05K 7/20

(52) U.S. Cl. CPC H05K 7/20263; H05K 7/20254; H05K 7/20927

(57) ABSTRACT

A liquid-cooled power supply chassis includes at least one power supply unit, at least one cold plate, a coolant input/output unit and a busbar. The cold plate is in thermal contact with the power supply unit to absorb a heat energy. Each cold plate has a coolant input port and a coolant output port. The coolant input/output unit includes a first conduit, a second conduit and a heat dissipation pipe. The first conduit connects the coolant input port and the heat dissipation pipe, and the second conduit connects the coolant output port and the heat dissipation pipe. The busbar includes a first copper busbar and a second copper busbar that are oppositely arranged, and the first copper busbar and the second copper busbar are electrically insulated from each other. The heat dissipation pipe is in thermal contact with the first and second copper busbar.

This application claims the benefits of U.S. provisional application Ser. No. 63/716,784, filed Nov. 6, 2024 and Taiwan application Serial No. 114105906, filed Feb. 18, 2025, the subject matters of which are incorporated herein by reference.

### BACKGROUND OF THE INVENTION

### Field of the Invention

The invention relates in general to a liquid cooling system, and more particularly to a liquid-cooled power supply chassis and a liquid-cooled power supply cabinet using the same.

### Description of the Related Art

Traditional liquid cooling architecture requires adding a cold plate or thermal copper plate for active heat dissipation in the cabinet. The heat energy is transferred to the coolant through the cold plate or thermal copper plate, and then the heat energy is taken away by the coolant. If the heat energy is not conducted to the outside of the cabinet by means of the cold plate or the thermal copper plate, the internal temperature of the cabinet will be too high and may cause damage to the components. In addition, the copper busbar with high current load will also generate heat, causing the internal temperature of the cabinet to be too high.

### SUMMARY OF THE INVENTION

The present invention relates to a liquid-cooled power supply chassis and a liquid-cooled power supply cabinet using the same, wherein the waste heat can be conducted to the outside of the chassis through the coolant to achieve rapid cooling.

According to one aspect of the present invention, a liquid-cooled power supply chassis is provided. The liquid-cooled power supply chassis includes at least a power supply unit, at least a cold plate, a coolant input/output unit, and a power bus. The cold plate is in thermal contact with the power supply unit to absorb heat energy. Each cold plate has a coolant input port and a coolant output port. The coolant input/output unit includes a first conduit, a second conduit and a heat dissipation manifold plate. The first conduit is connected to the coolant input port and the heat dissipation manifold plate, and the second conduit is connected to the coolant output port and the heat dissipation manifold plate. The power busbar includes a first copper busbar and a second copper busbar which are arranged opposite to each other, and the first copper busbar and the second copper busbar are electrically insulated from each other. The heat dissipation manifold plate is in thermal contact with the first copper busbar and the second copper busbar.

According to one aspect of the present invention, a liquid-cooled power supply cabinet is provided, including at least a liquid-cooled power supply chassis, a coolant input/output unit, and a power busbar. The liquid-cooled power supply chassis includes at least a power supply unit. The coolant input/output unit includes a first connection port, a second connection port, a heat dissipation manifold plate, a coolant input manifold and a coolant output manifold. The heat dissipation manifold plate is located in the liquid-cooled power supply chassis, the first connection port connects the heat dissipation manifold plate and the coolant input manifold, the second connection port connects the heat dissipation manifold plate and the coolant output manifold, and the power busbar includes a first copper busbar and a second copper busbar that are arranged opposite to each other, and the first copper busbar and the second copper busbar are electrically insulated from each other. The heat dissipation manifold plate is in thermal contact with the first copper busbar and the second copper busbar.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a schematic diagram of a liquid-cooled power supply chassis according to an embodiment of the present invention.

FIG. 2 is a three-dimensional schematic diagram of the copper busbar in FIG. 1.

FIGS. 3A and 3B are schematic diagrams showing the appearance and the exploded view of the coolant input/output unit in FIG. 1.

FIG. 4 is a schematic diagram illustrating the coolant conduction of a liquid-cooled power supply cabinet according to an embodiment of the present invention.

FIG. 5 is a schematic diagram of a liquid-cooled power supply chassis according to another embodiment of the present invention.

FIG. 6A is a three-dimension schematic diagram of the coolant input/output unit in FIG. 5.

FIG. 6B is a schematic cross-sectional view of the coolant input/output unit along line A-A in FIG. 6A.

FIG. 7 is a schematic diagram showing the coolant conduction of a liquid-cooled power supply cabinet according to another embodiment of the present invention.

FIG. 8 is a schematic diagram of a liquid-cooled power supply chassis according to another embodiment of the present invention.

FIGS. 9A and 9B are schematic diagrams showing the appearance of the coolant input/output unit in FIG. 8.

FIGS. 10 to 12 are schematic diagrams respectively illustrating coolant conduction of a liquid-cooled power supply cabinet according to another embodiment of the present invention.

### DETAILED DESCRIPTION OF THE INVENTION

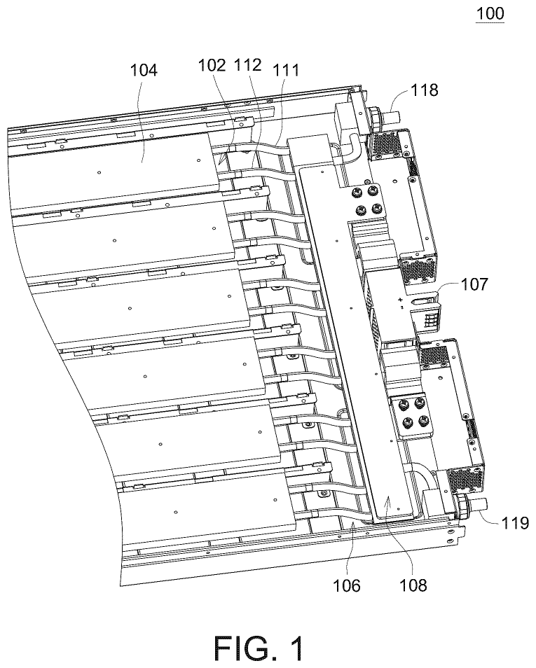

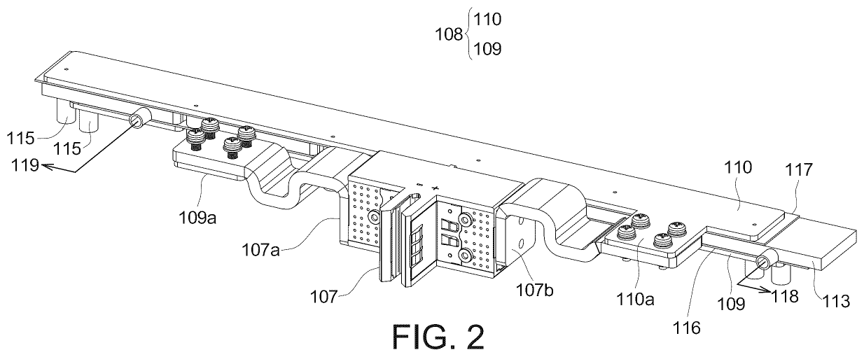

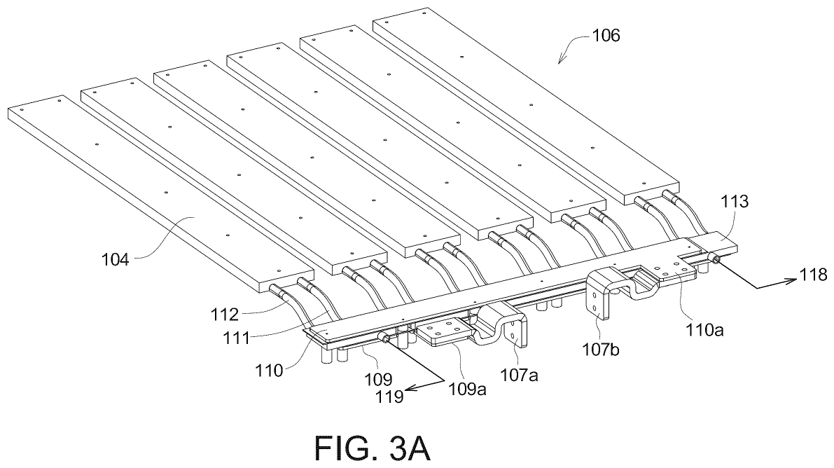

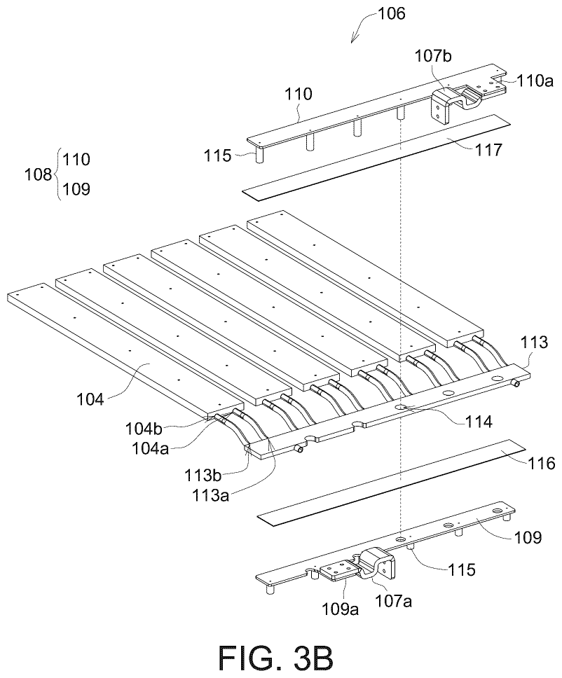

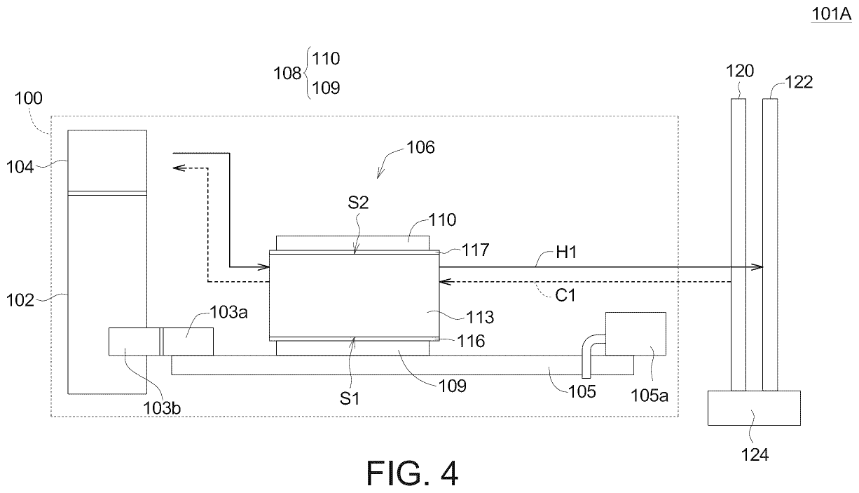

Referring to FIGS. 1 to 4, FIG. 1 is a schematic diagram of a liquid-cooled power supply chassis 100 according to an embodiment of the present invention, FIG. 2 is a three-dimensional schematic diagram of the power busbar 108 in FIG. 1, FIGS. 3A and 3B are schematic diagrams showing the appearance and the exploded view of the coolant input/output unit 106 in FIG. 1, and FIG. 4 is a schematic diagram of the coolant conduction of the liquid-cooled power supply cabinet 101 according to an embodiment of the present invention.

Referring to FIG. 1, the liquid-cooled power supply chassis 100 includes at least one power supply unit 102, at least one cold plate 104, a coolant input/output unit 106, and a power busbar 108. The number of the power supply unit 102 may include but is not limited to six, and the number of the cold plates 104 may include but is not limited to six. For example, in a standard-sized liquid-cooled power supply chassis 100, a cold plate 104 may be separately disposed above each power supply unit 102, and the cold plate 104 is in thermal contact with the power supply 102 to absorb heat energy. The cold plate 104 is, for example, a copper plate or an aluminum plate. Different from the immersion cooling configuration in which the heat-generating element is directly submerged in a non-conductive coolant. In the present embodiment, the coolant flowing into the cold plate 104 carries away the heat energy from the heating-generating element. Referring to FIG. 3B, each cold plate 104 has a coolant input port 104a and a coolant output port 104b. The coolant is, for example, water or other liquids. The coolant can flow out of the liquid-cooled power supply chassis 100 through the coolant input/output unit 106 and then recirculate back into the liquid-cooled power supply chassis 100 to continuously absorb the heat energy generated by the heat-generating elements, thereby improving the heat dissipation efficiency.

Referring to FIGS. 3A and 3B, the coolant input/output unit 106 includes a first conduit 111, a second conduit 112, and a heat dissipation manifold plate 113. In one embodiment, the number of the first conduit 111 may include but is not limited to six, and the number of the second conduit 112 may include but is not limited to six. The heat dissipation manifold plate 113 may be a manifold structure having a plurality of first ports 113a and a plurality of second ports 113b, wherein the number of the first ports 113a is the same as the number of the first conduit 111, and the number of the second ports 113b is the same as the number of the second conduit 112. Therefore, the first conduit 111 can be connected to the coolant input port 104a of each cold plate 104 and the first port 113a of the heat dissipation manifold plate 113 in a one-to-one configuration, so that the low-temperature coolant C1 (refer to FIG. 4) can flow into each cold plate 104. Similarly, the second conduit 112 can be connected to the coolant output port 104b of each cold plate 104 and the second port 113b of the heat dissipation manifold plate 113 in a one-to-one configuration, so that the high-temperature coolant H1 (refer to FIG. 4) can flow out of the cold plate 104.

Referring to FIGS. 1 and 2, a power busbar 108 is disposed in the liquid-cooled power supply chassis 100 to transmit DC power with a high current load (e.g., 1500 amperes). The DC power is obtained by, for example, inputting AC power into the circuit board 105 through the power connector 105a (FIG. 4) and converted by an AC-DC converter. When the DC power is transmitted through the power busbar 108, the power busbar 108 generates heat, thereby increasing the internal temperature of the liquid-cooled power supply chassis 100. In this embodiment, the heat of the power busbar 108 can be dissipated through the coolant input/output unit 106.

Referring to FIGS. 3A and 3B, the power busbar 108 includes a first copper busbar 109 and a second copper busbar 110 that are arranged opposite to each other. The first copper busbar 109 is, for example, located below the heat dissipation manifold plate 113, and the second copper busbar 110 is, for example, located above the heat dissipation manifold plate 113. The first copper busbar 109 is, for example, a busbar connected to the negative electrode 107a of the power connector 107 in FIG. 1. The first copper busbar 109 further includes a connecting part 109a, which is screwed to the negative electrode 107a and electrically connected to the negative electrode 107a. The second copper busbar 110 is, for example, a busbar connected to the positive electrode 107b of the power connector 107 in FIG. 1, the first copper busbar 109 and the second copper busbar 110 are electrically insulated from each other, and the second copper busbar 110 further includes a connecting part 110a, which is screwed to the positive electrode 107b and electrically connected to the positive electrode 107b. In one embodiment, in order to enable the second copper busbar 110 located above the heat dissipation manifold plate 113 to be electrically connected to the circuit board 105 (refer to FIG. 4) located below the heat dissipation manifold plate 113, the heat dissipation manifold plate 113 is provided with a plurality of vertical through holes 114, and the second copper busbar 110 is provided with a plurality of copper pillars 115, the number of the copper pillars 115 may include but is not limited to 5, and the positions of the copper pillars 115 correspond to the positions of the vertical through holes 114 in a one-to-one configuration, so that each copper pillar 115 can pass through the vertical through holes 114 of the heat dissipation manifold plate 113 and be connected to the circuit board 105. The circuit board 105 receives AC power from the power connector 150a, inputs the power into the power supply unit 102 through the circuit board 105 and the electrical connectors 103a, 103b for AC/DC conversion, and then transmits DC power to the power busbar 108 through the electrical connectors 103a, 103b and the circuit board 105. In addition, the first copper busbar 109 located below the heat dissipation manifold plate 113 is also provided with a plurality of copper pillars 115 for being electrically connected to the circuit board 105.

Referring to FIG. 4, the heat dissipation manifold plate 113 of the coolant input/output unit 106 is disposed between the first copper busbar 109 and the second copper busbar 110. The heat dissipation manifold plate 113, the first conduit 111, and the second conduit 112 of the coolant input/output unit 106 have been briefly described in FIGS. 3A and 3B, and is not described in detail here. In FIG. 4, the first thermal pad 116 is disposed on the first surface S1 of the heat dissipation manifold plate 113, and the second thermal pad 117 is disposed on the second surface S2 of the heat dissipation manifold plate 113. The first thermal pad 116 and the second thermal pad 117 are, for example, thermally conductive adhesives. The first copper busbar 109 can be in thermal contact with the first surface S1 through the first thermal pad 116, and the second copper busbar 110 can be in thermal contact with the second surface S2 through the second thermal pad 117, so as to conduct the waste heat of the copper busbar to the heat dissipation manifold plate 113, and then absorb the heat energy through the coolant inside the heat dissipation manifold plate 113, so as to conduct the heat energy to the outside of the liquid-cooled power supply chassis 100.

Referring to FIG. 4, the liquid-cooled power supply cabinet 101A includes at least a liquid-cooled power supply chassis 100, a coolant input/output unit 106, and a power busbar 108. The coolant input/output unit 106 includes a first connection port 118 (as shown in FIG. 1), a second connection port 119 (as shown in FIG. 1), a heat dissipation manifold plate 113, a coolant input manifold 120, and a coolant output manifold 122. The first connection port 118 connects the heat dissipation manifold plate 113 and the coolant input manifold 120, and the second connection port 119 connects the heat dissipation manifold plate 113 and the coolant output manifold 122. The configuration of the first connection port 118 and the second connection port 119 can also refer to FIG. 1. The first connection port 118 and the second connection port 119 are, for example, quick connectors, preferably liquid cooling blind plug quick connectors, such as UQDB-02 or UQDB-04 standard connectors, which can be used in tool-free installation liquid cooling systems. The coolant input manifold 120 and the coolant output manifold 122 may be connected to a coolant distribution unit 124 for heat exchange. The coolant distribution unit 124 can utilize a liquid pump unit (not shown) to connect each coolant input manifold 120 and each coolant output manifold 122 of a plurality of liquid-cooled power supply cabinets 101A to form a cooling circulation loop. In one embodiment, the coolant distribution unit 124 may include a liquid-to-liquid heat exchanger (not shown) or a liquid-to-air heat exchanger (not shown) to transfer heat energy in the coolant distribution unit 124 to an external environment.

Referring to FIG. 4, when the liquid-cooled power supply chassis 100 is disposed in a server and/or a power supply cabinet 101, the liquid-cooled power supply chassis 100 can be connected to the coolant input manifold 120 via the first connection port 118 so that the coolant enters each cold plate 104 via the heat dissipation manifold plate 113, and the liquid-cooled power supply chassis 100 can be connected to a coolant output manifold 122 via a second connection port 119 so that the coolant flows out of the liquid-cooled power supply chassis 100 via the heat dissipation manifold plate 113. At the same time, the waste heat generated by the power busbar 108 can also be absorbed by the coolant inside the heat dissipation manifold plate 113, thereby reducing the internal temperature of the liquid-cooled power supply cabinet 101.

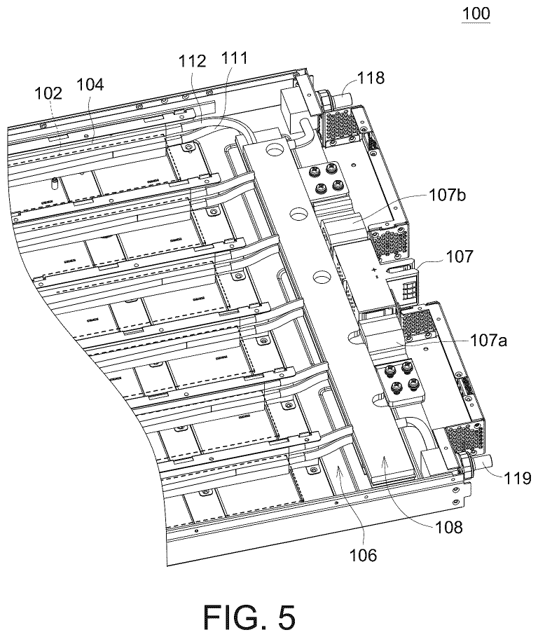

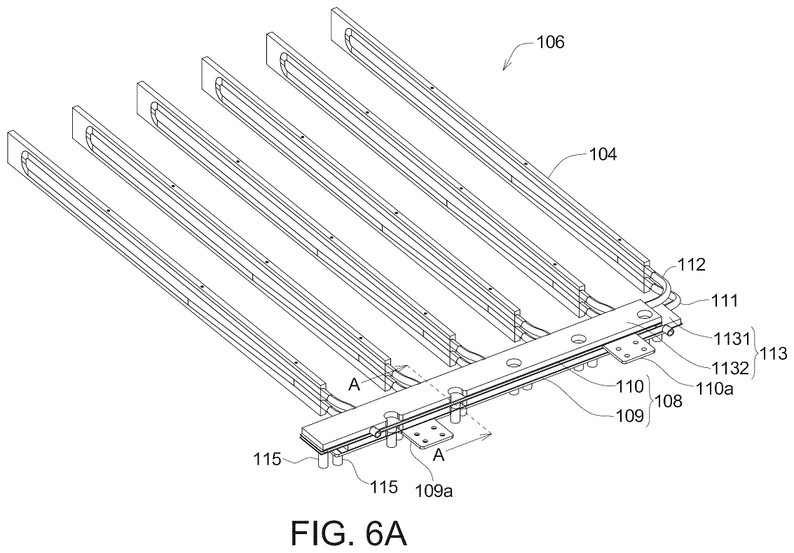

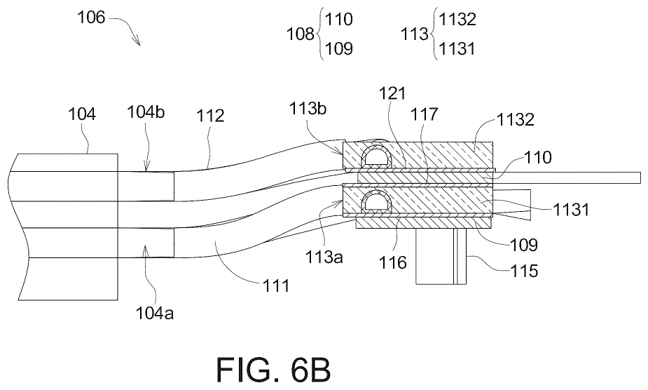

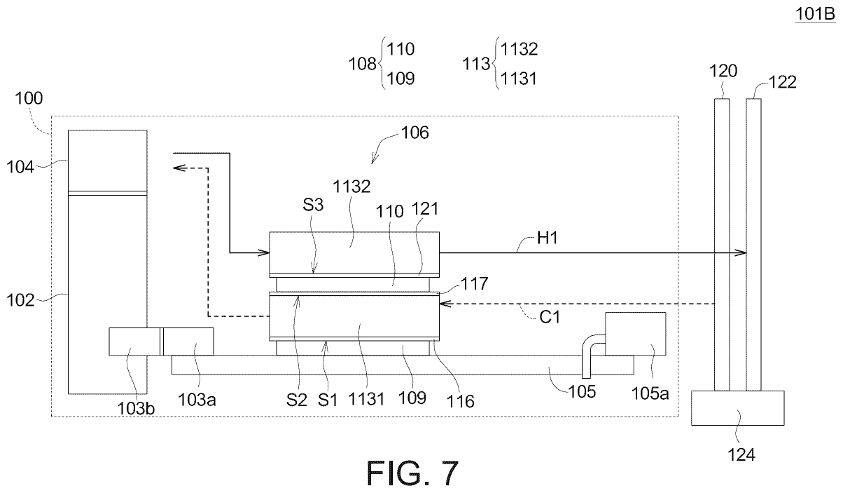

Referring to FIGS. 5 to 7, FIG. 5 is a schematic diagram of a liquid-cooled power supply chassis 100 according to another embodiment of the present invention, FIG. 6A is a three-dimensional schematic diagram of the coolant input/output unit 106 in FIG. 5, FIG. 6B is a cross-sectional schematic diagram of the coolant input/output unit 106 along A-A line in FIG. 6A, and FIG. 7 is a coolant conduction schematic diagram of a liquid-cooled power supply cabinet 101B according to another embodiment of the present invention.

Referring to FIG. 5, the liquid-cooled power supply chassis 100 includes at least one power supply unit 102 (for convenience of explanation, the power supply unit 102 is indicated by dashed lines), at least one cold plate 104, a coolant input/output unit 106, and a power busbar 108. The number of the power supply unit 102 may include but is not limited to six, and the number of the cold plate 104 may include but is not limited to six. For example, in a standard-sized liquid-cooled power supply chassis 100, a cold plate 104 may be separately disposed on the side of each power supply unit 102, and the cold plate 104 is in thermal contact with the power supply unit 102 to absorb heat energy. The cold plate 104 and the power supply unit 102 are generally arranged alternately in the chassis. The cold plate 104 is, for example, a copper plate or an aluminum plate. Different from the immersion cooling method in which the heat-generating element is directly immersed in a non-conductive coolant, the present embodiment utilizes the coolant flowing into the cold plate 104 to carry away the heat energy of the heat-generating element. Referring to FIG. 5, each cold plate 104 has a coolant input port 104a and a coolant output port 104b. The coolant is, for example, water or other liquids. The coolant can flow out of the liquid-cooled power supply chassis 100 through the coolant input/output unit 106 and then flow back into the liquid-cooled power supply chassis 100 through a cooling circulation method to continuously absorb the heat energy generated by the heat-generating elements to improve the heat dissipation efficiency.

Referring to FIGS. 6A and 6B, the coolant input/output unit 106 includes a first conduit 111, a second conduit 112, a first heat dissipation manifold plate 1131, and a second heat dissipation manifold plate 1132. In one embodiment, the number of the first conduits 111 may include but is not limited to six, and the number of the second conduits 112 may include but is not limited to six. The first heat dissipation manifold plate 1131 may be a manifold structure having a plurality of first ports 113a, and the second heat dissipation manifold plate 1132 may be a manifold structure having a plurality of second ports 113b. The number of the first ports 113a is the same as the number of the first conduit 111, and the number of the second ports 113b is the same as the number of the second conduit 112. Therefore, the first conduit 111 can be connected in a one-to-one configuration to the coolant input port 104a of each cold plate 104 and the first port 113a of the first heat dissipation manifold plate 1131, so that the low-temperature coolant C1 (refer to FIG. 7) can flow into each cold plate 104. The second conduit 112 can be connected to the coolant output port 104b of each cold plate 104 and the second port 113b of the second heat dissipation manifold plate 1132 in a one-to-one configuration, so that the high-temperature coolant H1 (refer to FIG. 7) can flow out of the cold plate 104.

Referring to FIG. 5, a power busbar 108 is disposed in the liquid-cooled power supply chassis 100 for transmitting DC power with a high current load (e.g., 1500 amperes). When the DC power is transmitted through the power busbar 108, the power busbar 108 generates heat, thereby increasing the internal temperature of the liquid-cooled power supply chassis 100. In this embodiment, the power busbar 108 can dissipate heat through the coolant input/output unit 106.

Referring to FIGS. 6A and 6B, the power busbar 108 includes a first copper busbar 109 and a second copper busbar 110 that are disposed opposite to each other. The first copper busbar 109 is, for example, located below the first heat dissipation manifold plate 1131. The second copper busbar 110 is, for example, located above the first heat dissipation manifold plate 1131, and the first heat dissipation manifold plate 1131 may be located between the first copper busbar 109 and the second copper busbar 110. In addition, the second heat dissipation manifold plate 1132 is, for example, located above the second copper busbar 110. The first copper busbar 109, the first heat dissipation manifold plate 1131, the second copper busbar 110 and the second heat dissipation manifold plate 1132 are stacked in sequence from bottom to top to form a vertically stacked heat dissipation structure. The first copper busbar 109 is, for example, a busbar connected to the negative electrode 107a of the power connector 107 in FIG. 5, and the second copper busbar 110 is, for example, a busbar connected to the positive electrode 107b of the power connector 107 in FIG. 5. The first copper busbar 109 and the second copper busbar 110 are electrically insulated from each other. In one embodiment, in order to enable the second bus copper bus 110 located above the first heat dissipation manifold plate 1131 to be electrically connected to the circuit board 105 located below the heat dissipation manifold plate 113 (refer to FIG. 7), the first heat dissipation manifold plate 1131 is provided with a plurality of vertical through holes 114, and the second bus copper bus 110 is provided with a plurality of copper pillars 115, the number of copper pillars 115 may include but is not limited to 5, and the positions of the copper pillars 115 correspond to the positions of the vertical through holes 114 in a one-to-one configuration, so that each copper pillar 115 can pass through the vertical through holes 114 of the first heat dissipation manifold plate 1131 and be connected to the circuit board 105. In addition, the first copper busbar 109 located below the first heat dissipation manifold plate 113 is also provided with a plurality of copper pillars 115 to electrically connect to the circuit board 105.

Referring to FIG. 7, the first heat dissipation manifold plate 1131 of the coolant input/output unit 106 is disposed between the first copper busbar 109 and the second copper busbar 110, and the second heat dissipation manifold plate 1132 is disposed above the second copper busbar 110. The first/second heat dissipation manifold plates 1131 and 1132, the first conduit 111 and the second conduit 112 of the coolant input/output unit 106 have been briefly described in FIGS. 6A and 6B and is not described in detail here. In FIG. 7, the first thermal pad 116 is disposed on the first surface S1 of the first heat dissipation manifold plate 1131, and the second thermal pad 117 is disposed on the second surface S2 of the first heat dissipation manifold plate 1131. The first thermal pad 116 and the second thermal pad 117 are, for example, thermally conductive adhesives. The first copper busbar 109 can be in thermal contact with the first surface S1 through the first thermal pad 116, and the second copper busbar 110 can be in thermal contact with the second surface S2 through the second thermal pad 117, so as to conduct the waste heat on the copper busbar to the first heat dissipation manifold plate 1131. The heat energy through the coolant inside the first heat dissipation manifold plate 1131 is absorbed and then conducted to the outside of the liquid-cooled power supply chassis 100. In addition, the third thermal pad 121 is disposed on the third surface S3 of the second heat dissipation manifold plate 1132. The second copper busbar 110 can be in thermal contact with the third surface S3 through the third thermal pad 121 to conduct the waste heat on the copper busbar to the second heat dissipation manifold plate 1132. The heat energy through the coolant inside the second heat dissipation manifold plate 1132 is absorbed so that the heat energy is conducted to the outside of the liquid-cooled power supply chassis 100.

Referring to FIG. 7, the liquid-cooled power supply cabinet 101B includes at least one liquid-cooled power supply chassis 100, a coolant input/output unit 106, and a power busbar 108. The coolant input/output unit 106 includes a first connection port 118 (see FIG. 5), a second connection port 119 (see FIG. 5), a first heat dissipation manifold plate 1131, a second heat dissipation manifold plate 1132, a coolant input manifold 120, and a coolant output manifold 122. The first connection port 118 connects the first heat dissipation manifold plate 1131 and the coolant input manifold 120, and the second connection port 119 connects the second heat dissipation manifold plate 1132 and the coolant output manifold 122. The configuration of the first connection port 118 and the second connection port 119 can refer to FIG. 5. The first connection port 118 and the second connection port 119 are, for example, quick connectors, preferably liquid cooling blind plug quick connectors, such as UQDB-02 or UQDB-04 standard connectors, which can be used in tool-free installation liquid cooling systems.

Referring to FIG. 7, when the liquid-cooled power supply chassis 100 is disposed in a server and/or power supply cabinet 101B, the liquid-cooled power supply chassis 100 can be connected to the coolant input manifold 120 via the first connection port 118 so that the coolant enters each cold plate 104 via the first heat dissipation manifold plate 1131. The liquid-cooled power supply chassis 100 can be connected to the coolant output manifold 122 via the second connection port 119 so that the coolant can flow out of the liquid-cooled power supply chassis 100 via the second heat dissipation manifold plate 1132. At the same time, the waste heat generated by the power busbar 108 can also be absorbed and transmitted through the coolant inside the first and second heat dissipation manifold plates 1131 and 1132, thereby reducing the internal temperature of the liquid-cooled power supply cabinet 101.

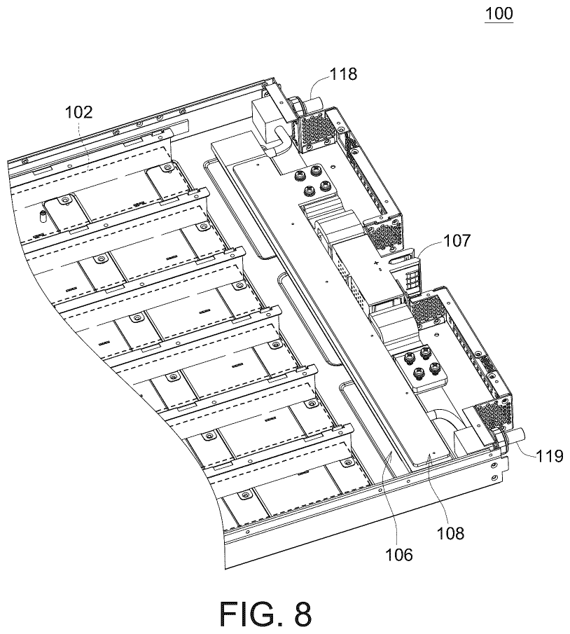

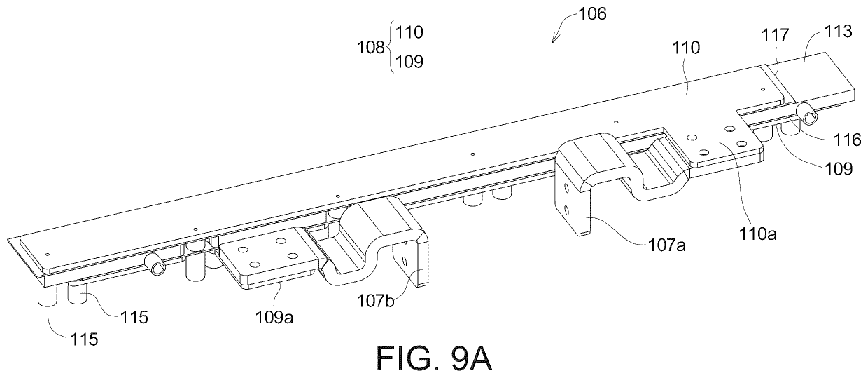

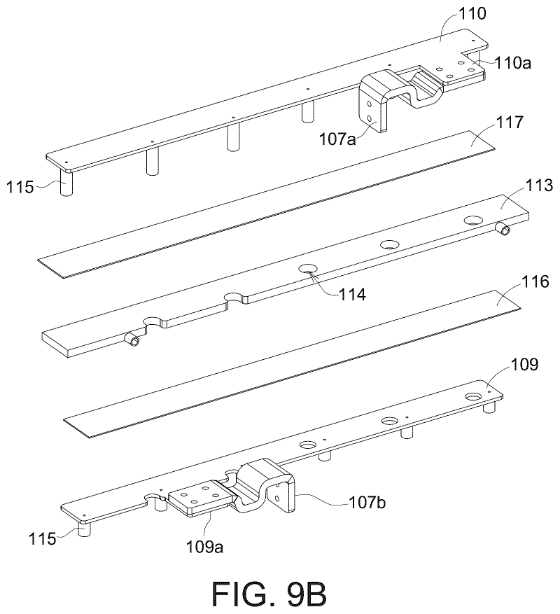

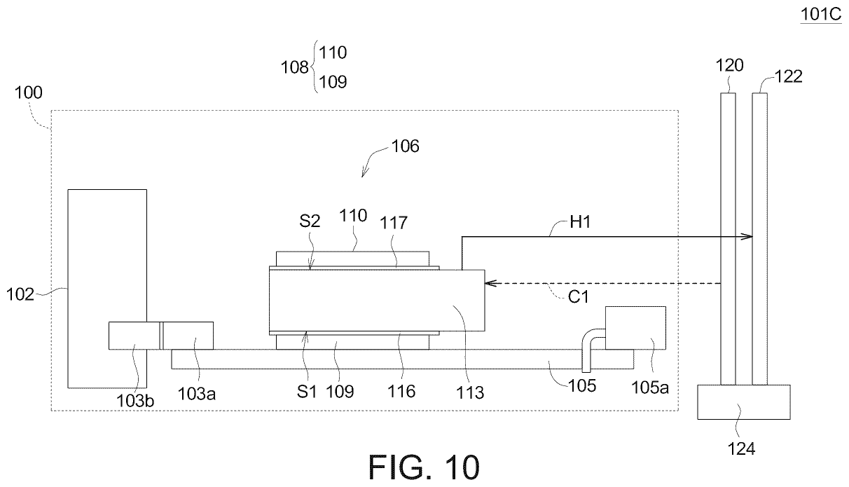

Refer to FIGS. 8 to 12, FIG. 8 is a schematic diagram of a liquid-cooled power supply chassis 100 according to another embodiment of the present invention, FIGS. 9A and 9B are schematic diagrams showing the appearance and the exploded view of the coolant input/output unit 106 in FIG. 8, and FIGS. 10 to 12 are respectively schematic diagrams of coolant conduction of liquid-cooled power supply cabinets 101C-101E according to another embodiment of the present invention.

Referring to FIG. 8, the liquid-cooled power supply chassis 100 includes at least one power supply unit 102, at least one cold plate (not shown), a coolant input/output unit 106, and a power busbar 108. The number of the power supply unit 102 may include but is not limited to six. Taking a standard-sized liquid-cooled power supply chassis 100 as an example, a cold plate or other heat sinks/fans may be separately disposed above each power supply unit 102 to dissipate heat so as to absorb the heat energy of the power supply unit 102. Therefore, the power supply unit 102 and the coolant input/output unit 106 of this embodiment are independently configured, and there is no need to use the coolant flowing into the cold plate to take away the heat energy of the heat generating element. The heat dissipation manifold plate 113 of the coolant input/output unit 106 mainly removes the waste heat generated by the power busbar 108.

Referring to FIG. 8, the power busbar 108 is disposed in the liquid-cooled power supply chassis 100 to transmit DC power with a high current load (e.g., 1500 amperes). When the DC power is transmitted through the power busbar 108, the power busbar 108 generates heat, thereby increasing the internal temperature of the liquid-cooled power supply chassis 100. In this embodiment, the power busbar 108 can dissipate heat through the coolant input/output unit 106.

Referring to FIGS. 9A and 9B, the power busbar 108 includes a first copper busbar 109 and a second copper busbar 110 that are arranged opposite to each other. The first copper busbar 109 is, for example, located below the heat dissipation manifold plate 113, and the second copper busbar 110 is, for example, located above the heat dissipation manifold plate 113. The first copper busbar 109 is, for example, a busbar connected to the negative electrode 107a of the power connector 107 in FIG. 8, and the second copper busbar 110 is, for example, a busbar connected to the positive electrode 107b of the power connector 107 in FIG. 8. The first copper busbar 109 and the second copper busbar 110 are electrically insulated from each other. In one embodiment, in order to enable the second copper busbar 110 located above the heat dissipation manifold plate 113 to electrically connect to the circuit board 105 located below the heat dissipation manifold plate 113 (refer to FIG. 10), the heat dissipation manifold plate 113 is provided with a plurality of vertical through holes 114, and the second bus copper bus 110 is provided with a plurality of copper pillars 115. The number of the copper pillars 115 may include but is not limited to 5, and the positions of the copper pillars 115 correspond to the positions of the vertical through holes 114 in a one-to-one configuration, so that each copper pillar 115 can pass through the vertical through holes 114 of the heat dissipation manifold plate 113 and be connected to the circuit board 105. In addition, the first copper busbar 109 located below the heat dissipation manifold plate 113 is also provided with a plurality of copper pillars 115 to electrically connect to the circuit board 105.

Referring to FIG. 10, the heat dissipation manifold plate 113 of the coolant input/output unit 106 is disposed between the first copper busbar 109 and the second copper busbar 110. The first thermal pad 116 is disposed on the first surface S1 of the heat dissipation manifold plate 113, and the second thermal pad 117 is disposed on the second surface S2 of the heat dissipation manifold plate 113. The first thermal pad 116 and the second thermal pad 117 are, for example, thermally conductive adhesives. The first copper busbar 109 can be in thermal contact with the first surface S1 through the first thermal pad 116, and the second copper busbar 110 can be in thermal contact with the second surface S2 through the second thermal pad 117, so as to conduct the waste heat on the copper busbar to the heat dissipation manifold plate 113. The heat energy through the coolant inside the heat dissipation manifold plate 113 is absorbed and then is conducted to the outside of the liquid-cooled power supply chassis 100.

Referring to FIG. 10, the liquid-cooled power supply cabinet 101C includes at least one liquid-cooled power supply chassis 100, a coolant input/output unit 106, and a power busbar 108. The coolant input/output unit 106 includes a first connection port 118, a second connection port 119, a heat dissipation manifold plate 113, a coolant input manifold 120, and a coolant output manifold 122. The first connection port 118 connects the heat dissipation manifold plate 113 and the coolant input manifold 120, and the second connection port 119 connects the heat dissipation manifold plate 113 and the coolant output manifold 122. The configuration of the first connection port 118 and the second connection port 119 can refer to FIG. 8. The first connection port 118 and the second connection port 119 are, for example, quick connectors, preferably liquid cooling blind plug quick connectors, such as UQDB-02 or UQDB-04 standard connectors, which can be used in tool-free installation liquid cooling systems.

Referring to FIG. 10, when the liquid-cooled power supply chassis 100 is disposed in a server and/or power supply cabinet 101C, the liquid-cooled power supply chassis 100 can be connected to the coolant input manifold 120 via the first connection port 118 so that the low-temperature coolant C1 enters the heat dissipation manifold plate 113 via the first connection port 118. The liquid-cooled power supply chassis 100 can be connected to the coolant output manifold 122 via the second connection port 119 so that the high-temperature coolant H1 flows out of the liquid-cooled power supply chassis 100 via the heat dissipation manifold plate 113. Therefore, the waste heat generated by the power busbar 108 can be absorbed by the coolant inside the heat dissipation manifold plate 113, thereby reducing the internal temperature of the liquid-cooled power supply cabinet 101.

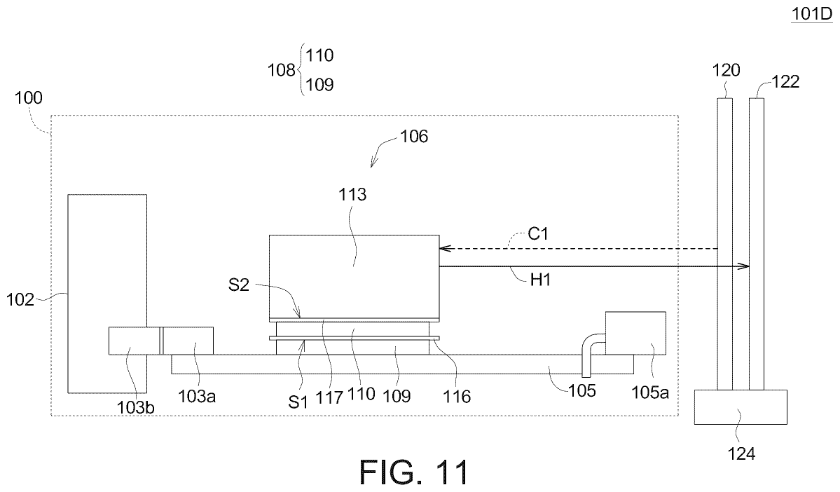

Referring to FIG. 11, in another embodiment, a liquid-cooled power supply cabinet 101D includes at least one liquid-cooled power supply chassis 100, a coolant input/output unit 106, and a power busbar 108. The coolant input/output unit 106 includes a first connection port 118, a second connection port 119, a heat dissipation manifold plate 113, a coolant input manifold 120, and a coolant output manifold 122. The description of the first connection port 118, the second connection port 119, the heat dissipation manifold plate 113, the coolant input manifold 120, and the coolant output manifold 122 may refer to the above embodiments, and is not repeated herein.

In FIG. 11, the heat dissipation manifold plate 113 of the coolant input/output unit 106 is arranged above the first copper busbar 109 and the second copper busbar 110. The first copper busbar 109, the second copper busbar 110 and the heat dissipation manifold plate 113 are stacked in sequence from bottom to top and are in thermal contact with each other through the first surface S1 and the second surface S2. The first thermal pad 116 is disposed between the first copper busbar 109 and the second copper busbar 110, and the second thermal pad 117 is disposed between the second copper busbar 110 and the heat dissipation manifold plate 113. The first thermal pad 116 and the second thermal pad 117 are, for example, thermally conductive adhesives. The first copper busbar 109 can be in thermal contact with the second copper busbar 110 through the first thermal pad 116, and the second copper busbar 110 can be in thermal contact with the heat dissipation manifold plate 113 through the second thermal pad 117. The waste heat on the copper busbar to the heat dissipation manifold plate 113 is conducted, and then absorbed through the coolant inside the heat dissipation manifold plate 113, so as to conduct the heat energy to the outside of the liquid-cooled power supply chassis 100.

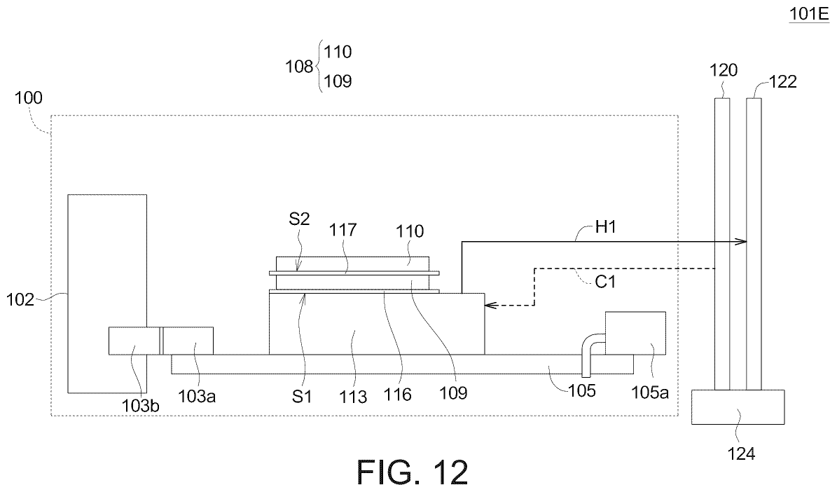

Referring to FIG. 12, in another embodiment, a liquid-cooled power supply cabinet 101E includes at least one liquid-cooled power supply chassis 100, a coolant input/output unit 106, and a power busbar 108. The coolant input/output unit 106 includes a first connection port 118, a second connection port 119, a heat dissipation manifold plate 113, a coolant input manifold 120, and a coolant output manifold 122. The description of the first connection port 118, the second connection port 119, the heat dissipation manifold plate 113, the coolant input manifold 120, and the coolant output manifold 122 may refer to the above embodiments, and is not repeated herein.

In FIG. 12, the heat dissipation manifold plate 113 of the coolant input/output unit 106 is arranged below the first copper busbar 109 and the second copper busbar 110. The heat dissipation manifold plate 113, the first copper busbar 109, the second copper busbar 110 are stacked in sequence from bottom to top and are in thermal contact with each other through the first surface S1 and the second surface S2. The first thermal pad 116 is disposed between the first copper busbar 109 and the heat dissipation manifold plate 113, and the second thermal pad 117 is disposed between the first copper busbar 109 and the second copper busbar 110. The first thermal pad 116 and the second thermal pad 117 are, for example, thermally conductive adhesives. The first copper busbar 109 can be in thermal contact with the heat dissipation manifold plate 113 through the first thermal pad 116, and the second copper busbar 110 can be in thermal contact with the first copper busbar 109 through the second thermal pad 117, so as to conduct the waste heat on the copper busbar to the heat dissipation manifold plate 113. The head energy is absorbed through the coolant inside the heat dissipation manifold plate 113, and then conducted to the outside of the liquid-cooled power supply chassis 100.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A liquid-cooled power supply chassis, comprising:
at least a power supply unit;
at least a cold plate, wherein the cold plate is in thermal contact with the power supply unit to absorb heat energy, the cold plate has a coolant input port and a coolant output port;
a coolant input/output unit, comprising a first conduit, a second conduit and a heat dissipation manifold plate, wherein the first conduit connects the coolant input port and the heat dissipation manifold plate, and the second conduit connects the coolant output port and the heat dissipation manifold plate; and
a power busbar, comprising a first copper busbar and a second copper busbar, wherein the first copper busbar and the second copper busbar are electrically insulated from each other,
wherein the heat dissipation manifold plate is in thermal contact with the first copper busbar and the second copper busbar.

2. The liquid-cooled power supply chassis of claim 1, wherein the heat dissipation manifold plate is disposed between the first copper busbar and the second copper busbar, the heat dissipation manifold plate includes a first surface and a second surface, the first copper busbar is in thermal contact with the first surface, and the second copper busbar is in thermal contact with the second surface.

3. The liquid-cooled power supply chassis of claim 2, further comprising a first thermal pad and a second thermal pad, wherein the first thermal pad is disposed on the first surface and the second thermal pad is disposed on the second surface.

4. The liquid-cooled power supply chassis of claim 1, wherein the second copper busbar is disposed between the first copper busbar and the heat dissipation manifold plate, the second copper busbar includes a first surface and a second surface, the first copper busbar is in thermal contact with the first surface, and the heat dissipation manifold plate is in thermal contact with the second surface.

5. The liquid-cooled power supply chassis of claim 4 further comprises a first thermal pad and a second thermal pad, wherein the first thermal pad is disposed on the first surface and the second thermal pad is disposed on the second surface.

6. The liquid-cooled power supply chassis of claim 1, wherein the heat dissipation manifold plate comprises a first heat dissipation manifold plate and a second heat dissipation manifold plate, the first heat dissipation manifold plate is disposed between the first copper busbar and the second copper busbar, the second copper busbar is disposed between the first heat dissipation manifold plate and the second heat dissipation manifold plate, the first heat dissipation manifold plate includes a first surface and a second surface, the first copper busbar is in thermal contact with the first surface, and the second copper busbar is in thermal contact with the second surface, and the second heat dissipation manifold plate includes a third surface, and the second copper busbar is in thermal contact with the third surface.

7. The liquid-cooled power supply chassis of claim 6, further comprising a first thermal pad, a second thermal pad and a third thermal pad, wherein the first thermal pad is disposed on the first surface, the second thermal pad is disposed on the second surface, and the third thermal pad is disposed on the third surface.

8. The liquid-cooled power supply chassis of claim 1, further comprising a circuit board, the circuit board is electrically connected to the power supply unit, wherein at least one of the first copper busbar and the second copper busbar comprises at least a copper pillar, the copper pillar passes through the heat dissipation manifold plate and is connected to the circuit board.

9. The liquid-cooled power supply chassis of claim 1, further comprising a power connector having a positive electrode and a negative electrode, wherein the first copper busbar and the second copper busbar are respectively connected to the positive electrode and the negative electrode.

10. A liquid-cooled power supply cabinet, comprising:
at least a liquid-cooled power supply chassis including at least a power supply unit;
a coolant input/output unit, comprising a first connection port, a second connection port, a heat dissipation manifold plate, a coolant input manifold, and a coolant output manifold, wherein the heat dissipation manifold plate is located in the liquid-cooled power supply chassis, the first connection port connects the heat dissipation manifold plate and the coolant input manifold, and the second connection port connects the heat dissipation manifold plate and the coolant output manifold; and
a power busbar, comprising a first copper busbar and a second copper busbar, wherein the first copper busbar and the second copper busbar are electrically insulated from each other,
wherein the heat dissipation manifold plate is in thermal contact with the first copper busbar and the second copper busbar.

11. The liquid-cooled power supply cabinet of claim 10, wherein the liquid-cooled power supply cabinet further comprises at least a cold plate, the cold plate is in thermal contact with the power supply unit to absorb heat energy and has a coolant input port and a coolant output port, and the coolant input port and the coolant output port are respectively connected to the heat dissipation manifold plate.

12. The liquid-cooled power supply cabinet of claim 11, wherein the coolant input/output unit further comprises a first conduit and a second conduit, the first conduit connects the coolant input port and the heat dissipation manifold plate, and the second conduit connects the coolant output port and the heat dissipation manifold plate.

13. The liquid-cooled power supply cabinet of claim 10, wherein the heat dissipation manifold plate is disposed between the first copper busbar and the second copper busbar, the heat dissipation manifold plate includes a first surface and a second surface, the first copper busbar is in thermal contact with the first surface, and the second copper busbar is in thermal contact with the second surface.

14. The liquid-cooled power supply cabinet of claim 13, further comprising a first thermal pad and a second thermal pad, wherein the first thermal pad is disposed on the first surface and the second thermal pad is disposed on the second surface.

15. The liquid-cooled power supply cabinet of claim 10, wherein the second copper busbar is disposed between the first copper busbar and the heat dissipation manifold plate, the second copper busbar includes a first surface and a second surface, the first copper busbar is in thermal contact with the first surface, and the heat dissipation manifold plate is in thermal contact with the second surface.

16. The liquid-cooled power supply cabinet of claim 15, further comprising a first thermal pad and a second thermal pad, wherein the first thermal pad is disposed on the first surface and the second thermal pad is disposed on the second surface.

17. The liquid-cooled power supply cabinet of claim 10, wherein the heat dissipation manifold plate comprises a first heat dissipation manifold plate and a second heat dissipation manifold plate, the first heat dissipation manifold plate is disposed between the first copper busbar and the second copper busbar, the second copper busbar is disposed between the first heat dissipation manifold plate and the second heat dissipation manifold plate, the first heat dissipation manifold plate includes a first surface and a second surface, the first copper busbar is in thermal contact with the first surface, and the second copper busbar is in thermal contact with the second surface, the second heat dissipation manifold plate includes a third surface, and the second copper busbar is in thermal contact with the third surface.

18. The liquid-cooled power supply cabinet of claim 17, further comprising a first thermal pad, a second thermal pad and a third thermal pad, wherein the first thermal pad is disposed on the first surface, the second thermal pad is disposed on the second surface, and the third thermal pad is disposed on the third surface.

19. The liquid-cooled power supply cabinet of claim 10, wherein at least one of the first copper busbar and the second copper busbar comprises at least one copper pillar, the copper pillar passes through the heat dissipation manifold plate.

20. The liquid-cooled power supply cabinet of claim 10, further comprises a power connector having a positive electrode and a negative electrode, wherein the first copper busbar and the second copper busbar are respectively connected to the positive electrode and the negative electrode.
